(19) United States
(12) Patent Application Publication
(10) Pub. No.: US 2008/0026145 A1
(43) Pub. Date: Jan. 31, 2008

(54) Re-useable offset printing plate and method for producing the printing plate

(75) Inventors: Peter Arthur Boehmer, Zemmer/Rodt (DE); Dieter Junkers, Aach (DE)

Correspondence Address: LERNER GREENBERG STEMER LLP, P O BOX 2480, HOLLYWOOD, FL, 33022-2480, US

(73) Assignee: Heidelberger Druckmaschinen AG

(21) Appl. No.: 11/821,153

(22) Filed: Jun. 22, 2007

Related U.S. Application Data
(63) Continuation of application No. PCT/EP05/13672, filed on Dec. 15, 2005.

(30) Foreign Application Priority Data
Dec. 22, 2004 (EP) 04 078 489.4

(51) Int. Cl. C23C 16/06; B41C 3/00; B41N 1/04

(52) U.S. Cl. 427/250; 101/395; 101/401.1

(57) ABSTRACT

An offset printing plate for sheet fed offset printing, the offset printing plate contains a metal substrate and a top layer having low thermal conductivity. The metal substrate is an aluminum substrate having a thickness between 0.05 and 2 mm. An intermediate layer having low thermal conductivity and formed of anodized aluminum is provided on top of the metal substrate in a thickness of between 1 and 25 μm. A top layer formed of titanium and/or molybdenum, or an alloy thereof, is provided on the intermediate layer in a thickness of between 1 and 10 μm, particularly between 1 and 10 μm.

### CROSS-REFERENCE TO RELATED APPLICATIONS

This is a continuing application, under 35 U.S.C. § 120, of copending international application No. PCT/EP2005/013672, filed Dec. 15, 2005, which designated the United States; this application also claims the priority, under 35 U.S.C. § 119, of European patent application No. 04078489.4, filed Dec. 22, 2004; the prior applications are herewith incorporated by reference in their entirety.

### BACKGROUND OF THE INVENTION

### Field of the Invention

The invention relates to an offset printing plate for sheet fed offset printing and to a method for producing such an offset printing plate.

For offset printing of a picture a raster of dots is printed, which dots are hardly visible to the bare eye. For color prints, usually several monochrome rasters are necessary. Mainly, four basic colors are used: cyan, magenta, yellow and black. Each raster is printed in a printing unit of a printing machine.

For each raster a separate offset printing plate has to be used. The surface of an offset printing plate has been prepared such that certain parts of it are water repellent, whereas others will be wetted by the rollers of a dampening unit that is part of each printing unit in the printing machine. The printing ink, which is applied using an inking unit in each printing unit, will be repelled by the wet portions and will adhere to the dry portions of the offset printing plate. In this way a pattern of inked dots is created on the plate, and is transferred to a substrate such as paper or cardboard.

It will be clear from the above that for each color printing usually four offset printing plates are necessary, and that for each folder or book a large number of offset printing plates are necessary, up to hundreds. These offset plates can be used only once.

The offset printing plates used nowadays are made from aluminum sheet, that is coated with a special organic layer of several hundreds micrometer in thickness. The organic layer is removed by laser light such that dots are formed; where no laser light has been applied, the organic layer is kept on the aluminum sheet. The part of the plate (sheet) where the organic layer is present will be wetted by the dampening unit; however, the dots will not be wetted and the printing ink will adhere to these dry dots. The ink will not adhere to the wet portions of the sheet. With the laser thus the required non-wettable pattern of dots is produced on the offset printing plate. Instead of laser light it is also possible to use UV light.

To provide a more economical offset printing a printing plate that can be used many times is proposed, since in that way a large number of offset printing plates can be saved and less chemicals are needed. European patent EP 1 151 857, corresponding to U.S. Pat. No. 6,520,088, proposes to use a metallic titanium layer on a metal substrate or a plastic layer or film, or even an offset plate or roll that is entirely made of metallic titanium. The titanium can be a titanium alloy in which the proportion of titanium is preferably between 95 and 100%.

However, in practice it has been shown that this offset printing form does not work. The organic layer has to be removed from the total surface of the offset plate by using laser light or UV light, but by doing so the surface of the offset plate is damaged and the offset plate cannot be reused. Moreover, titanium is a rather expensive metal and the proposed offset printing form appears to need quite a lot of titanium.

### SUMMARY OF THE INVENTION

It is accordingly an object of the invention to provide a re-usable offset printing plate and a method for producing such a printing plate which overcome the above-mentioned disadvantages of the prior art devices and methods of this general type, in which the offset printing plate can be used more than once. It is another object of the invention to provide an offset printing plate that is economically feasible for the printing industry and also technically feasible.

With the foregoing and other objects in view there is provided, in accordance with the invention, an offset printing plate for sheet fed offset printing. The offset printing plate contains a metal substrate and a top layer having a low thermal conductivity. The metal substrate is an aluminum substrate having a thickness between 0.05 and 2 mm. An intermediate layer having a low thermal conductivity formed of anodized aluminum is provided on top of the metal substrate in a thickness between 1 and 25 μm. A top layer formed of titanium and/or molybdenum, or an alloy thereof, provided on the intermediate layer in a thickness of less than 10 μm, particularly between 1 and 10 μm.

The offset printing plate according to the invention has a top layer of titanium or molybdenum which is very thin, the titanium or molybdenum having a low thermal conductivity as compared to other metals, and below the top layer an intermediate layer of aluminum-oxide that is thermally isolating on the aluminum substrate. With this sequence of layers, the offset printing plate according to the invention is suitable for applying an organic coating that will be removed when treated with laser light or UV light. The removal of the organic coating, either to form the dots for the printing ink or to remove the organic layer from the organic layer in total, does not damage the offset printing plate due to the sequence of layers according to the invention. The thin top layer of titanium or molybdenum with a low thermal conductivity on the isolating layer of anodized aluminum will keep the heat of the laser or UV light for the required time in the right place to remove the organic coating, without damaging the offset printing plate. To be able to take effect, the top layer has to have a thickness of less than 10 μm. Titanium and molybdenum are the only commercially available metals having the required low thermal conductivity for the lop layer.

The isolating intermediate layer prevents the heat from leaking away into the substrate, which substrate is necessary as support in the printing machine. The intermediate layer need not be very thick to provide the required isolating function. It has been found that only anodized aluminum is technically feasible and is commercially available on the market to fulfill the function of the isolating intermediate layer. Most other materials are too brittle or cannot withstand the heat often enough, or are too complex to be used on a large scale.

After the removal of the organic layer from the offset printing plate, a new organic layer can be formed on the offset printing plate that can be treated with laser or UV light to form dots for printing ink so as to print a new raster of dots.

In the context of this invention, with aluminum is meant an aluminum alloy, such as the AA Ixxx series.

It might be possible to provide an anodized aluminum layer with a Ti or Mo layer on top of an aluminum roller or a roller provided with an aluminum layer, but for practical purposes an offset printing plate is preferred. The same holds for a circumferentially closed sleeve.

Of course it will be possible to provide an additional layer below the aluminum substrate; however, this appears to be not economically interesting.

Preferably the top layer is provided using physical vapor deposition (PVD). PVD is a very suitable technology to apply a thin layer of metal on a substrate, especially when the metal layer is difficult or impossible to apply in another way, such as electroplating or cladding.

The metal substrate preferably has a thickness between 0.1 and 0.5 mm, more preferably a thickness of 0.3 mm. Usually offset printing plates have a thickness between 0.1 and 0.5 mm, to give the offset sheet the required stiffness and bendability around an offset roll. A thickness of 0.3 mm is preferred for most commercially seized offset plates.

The intermediate layer preferably has a thickness between 2 and 10 μm, more preferably a thickness between 3 and 5 μm. Since the intermediate layer has to have an isolating function for the top layer, the thickness of the intermediate layer is determined by the thickness of the top layer and the amount of energy introduced in the top layer by the laser light or UV light. A thickness of 2 to 10 μm is usually sufficient, and a thickness between 3 and 5 μm is preferred also in view of the providing of the anodized layer on the aluminum layer.

The top layer preferably has a thickness between 2 and 5 μm, more preferably a thickness between 3 and 4 μm. The thickness of the top layer determines the amount of energy of the laser or UV light that can be absorbed by the top layer, and the sharpness of the dots of the raster that can be produced. A thickness between 3 and 4 μm has been found to be optimal, also in view of the applying of the top layer using PVD.

According to another aspect of the invention, a method for producing an offset printing plate as described above is provided, includes the steps of: providing an aluminum substrate having a thickness between 0.05 and 2 mm; providing an intermediate layer of anodized aluminum having a thickness between 1 and 25 μm on the metal substrate; and providing a top layer of titanium and/or molybdenum or an alloy thereof having a thickness of less than 10 μm, particularly between 1 and 10 μm, on the intermediate layer.

Using this method, an offset printing plate is produced that can be used many times, that is technically feasible and that is economically attractive since little titanium or molybdenum is used.

Preferably, the top layer of titanium and/or molybdenum or an alloy thereof is provided using physical vapor deposition (PVD). The advantages of coating a thin layer of molybdenum or titanium or an alloy thereof using PVD have been elucidated above.

According to a preferred embodiment the offset printing plate is subjected to a skin pass operation. A metal layer provided by PVD usually has pin holes over the total thickness of the layer, which might be disadvantageous in view of for instance corrosion resistance. A simple and effective way to get rid of the pinholes is to subject the plate to a skin pass operation, by which the thickness of the plate is reduced a few percent and by which the pin holes are closed.

However, it is also possible to supply the top layer in two (or more) steps using PVD, so each sub-layer has pin holes that are only present over half the thickness of the top layer. This method though is usually uneconomical.

Preferably the aluminum substrate is anodized to form an intermediate layer of anodized aluminum. The layer of anodized aluminum is the reason why a substrate of aluminum has been chosen. Moreover, a substrate of another metal is usually either too expensive or not enough resistant to corrosion, or both.

According to a preferred embodiment the offset printing plate is produced as a continuous strip. In this way a strip of aluminum can be anodized and coated in an economical way, and afterwards be cut into offset printing sheets with the required dimensions.

Other features which are considered as characteristic for the invention are set forth in the appended claims.

Although the invention is described herein as embodied in a re-usable offset printing plate and a method for producing the printing plate, it is nevertheless not intended to be limited to the details described, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments.

### DETAILED DESCRIPTION OF THE INVENTION

The invention will be elucidated by describing an exemplary, preferred embodiment.

As a substrate for the offset printing plates, an aluminum strip EN 3103 H27 having a thickness of 0.3 mm is used having a layer of anodized aluminum with a thickness between 2 and 3 μm on the aluminum due to natural anodizing, which is sealed.

The anodizing is performed using an alkaline cleaner, after which the aluminum strip is chemically pickled; then the strip is anodized for 1 to 2 minutes at approximately 8 A/dm² to form an anodized layer which is sealed during approximately 10 minutes at 40° C. The sealing is used to close the pores.

Anodizing of aluminum is a well-known technique as such. The anodizing provides a hexagonal Al₂O₃ columnar structure, as known to the skilled person.

After the sealing, the anodized aluminum strip is coated with a layer of pure titanium by physical vapor deposition (PVD). During this process titanium is evaporated in a vacuum chamber in which the aluminum strip is transported and the titanium is deposited on the aluminum strip. The PVD process is performed to form a titanium layer of approximately 3 μm.

Before the PVD process is used, the anodized aluminum strip is pre-treated using medium frequency (MF) ion etching to clean the surface. The titanium is evaporated using electron beam evaporation, the electron beam having an energy level to introduce 40 to 50 kW per kg titanium. The strip temperature is approximately 230° C. and the process pressure is 1 to 3×10⁻⁴ mbar.

It is also possible to coat the anodized aluminum strip with a layer of pure molybdenum by physical vapor deposition. Here, the energy level of the electron beam is such that 25 to 30 kW per kg molybdenum, and the strip temperature is approximately 230° C. The other conditions are the same as for titanium.

If necessary, the coated strip is subjected to a skin pass operation to close the pores present in the titanium or molybdenum layer.

For commercial production, an aluminum strip will have a width of for instance 800 mm and a length of for instance 1,000 meter.

The coated strip can than be cut into suitable pieces to produce offset printing plates suitable for the printing industry.

It will be understood that the cutting to pieces of the aluminum strip can be performed prior to the PVD coating of the titanium or molybdenum layer, which pieces can than be PVD coated batch-wise, but usually this is less cost-effective.

1. An offset printing plate for a sheet fed offset printing, the offset printing plate comprising:
a metal substrate formed of aluminum and having a thickness between 0.05 and 2 mm;
an intermediate layer having low thermal conductivity and formed of anodized aluminum disposed on top of said metal substrate, said intermediate layer having a thickness between 1 and 25 μm; and
a top layer having low thermal conductivity and formed of at least one of titanium, molybdenum, and an alloy thereof, disposed on said intermediate layer, said top layer having a thickness of less than 10 μm.

2. The offset printing plate according to claim 1, wherein said top layer is producing using a physical vapor deposition process.

3. The offset printing plate according to claim 1, wherein said thickness of said metal substrate is between 0.1 and 0.5 mm.

4. The offset printing plate according to claim 1, wherein said thickness of said intermediate layer is between 2 and 10 μm.

5. The offset printing plate according to claim 1, wherein said thickness of said top layer is between 2 and 5 μm.

6. The offset printing plate according to claim 1, wherein said thickness of said intermediate layer is between 1 and 10 μm.

7. The offset printing plate according to claim 3, wherein said thickness of said metal substrate is 0.3 mm.

8. The offset printing plate according to claim 4, wherein said thickness of said intermediate layer is between 3 and 5 μm.

9. The offset printing plate according to claim 5, wherein said thickness of said top layer is between 3 and 4 μm.

10. The offset printing plate according to claim 1, wherein said thickness of said top layer is between 1 and 10 μm.

11. A method for producing an offset printing plate, which comprises the steps of:
providing an aluminum substrate having a thickness between 0.05 and 2 mm;
providing an intermediate layer of anodized aluminum having a thickness between 1 and 25 μm on the aluminum substrate; and
providing a top layer of at least one of titanium, molybdenum and an alloy thereof having a thickness of less than 10 μm on the intermediate layer.

12. The method according to claim 11, which further comprises producing the top layer using a physical vapor deposition process.

13. The method according to claim 12, which further comprises subjecting the offset printing plate to a skin pass operation.

14. The method according to claim 12, which further comprises anodizing the aluminum substrate to form the intermediate layer formed of anodized aluminum.

15. The method according to claim 11, which further comprises producing the offset printing plate as a continuous strip.

16. The method according to claim 11, which further comprises producing the thickness of the top layer to be between 1 and 10 μm.
